(19) United States
(12) Patent Application Publication
(10) Pub. No.: US 2021/0202535 A1
(43) Pub. Date: Jul. 1, 2021

(54) DISPLAY PANEL AND INTELLIGENT TERMINAL

(71) Applicant: Wuhan China Star Optoelectronics Semiconductor Display Technology Co., Ltd., Wuhan (CN)

(72) Inventors: Liang SUN, Wuhan (CN); Shoucheng WANG, Wuhan (CN); Mian ZENG, Wuhan (CN); Jun LI, Wuhan (CN)

(73) Assignee: Wuhan China Star Optoelectronics Semiconductor Display Technology Co., Ltd., Wuhan (CN)

(21) Appl. No.: 16/623,781

(22) PCT Filed: Apr. 18, 2019
(86) PCT No.: PCT/CN2019/083147

§ 371 Date: Dec. 18, 2019

(30) Foreign Application Priority Data
Jan. 2, 2019 (CN) 201910002667.8

(51) Int. Cl. H01L 27/12

(52) U.S. Cl. CPC H01L 27/1214

(57) ABSTRACT

A display panel and an intelligent terminal. The display panel including at least one transparent region and a display region, wherein the transparent region has two-way light transmission, and has a transparent function and a display function, a sensor component is disposed under the transparent region, the display region surrounds the transparent region, a brightness of the transparent region is less than or equal to a brightness of the display region.

### BACKGROUND OF INVENTION

### Field of Invention

The present invention relates to the field of electronic display, and in particular, to a display and an intelligent terminal.

### Description of Prior Art

With the popularity of smart devices and the continuous development of display technology, functions of display panels have also increased. Present mobile device displays are provided with display-isolated cameras, which occupy display regions of the mobile devices and limit screen ratio of the mobile device. As an indispensable part of today's mobile device, how to integrate cameras within display regions to maximize the screen ratio is an urgent problem.

### Technical Problems

In the prior art, cameras of the mobile devices are usually designed outside display screens, thereby the display screens need to be sized to accommodate the cameras. As a result, the camera area cannot display normally and has to perform profile cut.

### SUMMARY OF INVENTION

The present invention provides a display panel and an intelligent terminal, which can integrate light sensor into the display panel to avoid profile cutting.

Specifically, the present invention provides a display panel comprising at least one transparent region and a display region, wherein the transparent region has two-way light transmission, and has a transparent function and a display function, a sensor component is disposed under the transparent region, the display region surrounds the transparent region, a brightness of the transparent region is less than or equal to a brightness of the display region;

wherein a number of the at least one transparent region is one;

wherein the transparent region is located at a side of the display panel, and at least one side of the transparent region overlaps with at least one side of the display panel;

or the transparent region is located at a center of the display panel and surrounded by the display region.

According to one aspect of the invention, wherein a number of the transparent regions is plural;

wherein the transparent regions are separated by the display region;

a position of at least one of the sides of any one of the transparent regions overlaps with at least one side of the display panel; or

the transparent region is located at a center of the display panel and is surrounded by the display region.

According to one aspect of the invention, wherein a density of pixel units in the transparent region is less than or equal to a density of pixel units in the display region;

wherein the transparent region comprises a plurality of pixel units and a plurality of transparent units, the pixel units are spaced apart from the transparent unit, and a region of the pixel units is less than or equal to an region of the transparent units;

wherein the display region comprises a plurality of pixel units.

According to one aspect of the invention, wherein the display panel comprises a thin film transistor layer electrically connected to the pixel units;

wherein the thin film transistor layer located under the transparent region comprise a thin film transistor corresponding to the pixel units and a transparent laminate corresponding to the transparent unit;

wherein thin film transistor layer located under the display region includes a thin film transistor corresponding to the pixel units.

According to one aspect of the invention, wherein a density of the thin film transistor in the thin film transistor layer under the transparent region is smaller than a density of a thin film transistor in a thin film transistor layer under the display region.

According to one aspect of the invention, wherein the thin film transistor comprises:

a substrate;

an active region on the substrate, the active region comprises a channel region and a source region and a drain region on both sides of the channel region;

a gate dielectric layer covering the active region;

a gate metal layer covering the gate dielectric layer, a vertical projection of the gate metal layer covering the channel region;

an interlayer dielectric layer covering the active region;

a source/drain metal layer penetrating the interlayer dielectric layer and electrically connected to the source region and drain region;

a planarization layer covering the interlayer dielectric layer and the source/drain metal layer;

an electrode layer penetrating the planarization layer and electrically connected to the source/drain metal layer;

and a pixel defining layer on the planarization layer and exposing the electrode layer.

According to one aspect of the invention, wherein the transparent laminate comprises:

a first substrate formed by a substrate extension in an adjacent thin film transistor;

a first dielectric layer covering the substrate, the first dielectric layer is formed by an extension of a gate dielectric layer in an adjacent thin film transistor;

a second dielectric layer covering the gate dielectric layer, the second dielectric layer is formed by an extension of an interlayer dielectric layer in an adjacent thin film transistor; and

the thin film transistor further comprises a source/drain wiring layer electrically connected to the source/drain metal layer, and a gate wiring layer electrically connected to the gate metal layer;

wherein a density of source/drain wirings in the thin film transistor under the transparent region that is less than or equal to a density of source/drain wirings located under the display region;

wherein a density of gate wirings of the gate wiring layer below the transparent region is less than or equal to a density of gate wirings of the gate wiring layer under the display region;

wherein projections of the source/drain trace layer and the gate trace layer in a horizontal direction separate from a projection of the transparent stack in the horizontal direction.

The present invention further provides a display panel comprising at least one transparent region and a display region, wherein the transparent region has two-way light transmission, and has a transparent function and a display function, a sensor component is disposed under the transparent region, the display region surrounds the transparent region, a brightness of the transparent region is less than or equal to a brightness of the display region.

According to one aspect of the invention, wherein a number of the at least one transparent region is one;

wherein the transparent region is located at a side of the display panel, and at least one side of the transparent region overlaps with at least one side of the display panel;

or the transparent region is located at a center of the display panel and surrounded by the display region.

According to one aspect of the invention, wherein a number of the transparent regions is plural;

wherein the transparent regions are separated by the display region;

a position of at least one of the sides of any one of the transparent regions overlaps with at least one side of the display panel; or

the transparent region is located at a center of the display panel and is surrounded by the display region.

According to one aspect of the invention, wherein a density of pixel units in the transparent region is less than or equal to a density of pixel units in the display region;

wherein the transparent region comprises a plurality of pixel units and a plurality of transparent units, the pixel units are spaced apart from the transparent unit, and an region of the pixel units is less than or equal to an region of the transparent units;

wherein the display region comprises a plurality of pixel units.

According to one aspect of the invention, wherein the display panel comprises a thin film transistor layer electrically connected to the pixel units;

wherein the thin film transistor layer located under the transparent region comprise a thin film transistor corresponding to the pixel units and a transparent laminate corresponding to the transparent unit;

wherein thin film transistor layer located under the display region includes a thin film transistor corresponding to the pixel units.

According to one aspect of the invention, wherein a density of the thin film transistor in the thin film transistor layer under the transparent region is smaller than a density of a thin film transistor in a thin film transistor layer under the display region.

According to one aspect of the invention, wherein the thin film transistor comprises:

a substrate;

an active region on the substrate, the active region comprises a channel region and a source region and a drain region on both sides of the channel region;

a gate dielectric layer covering the active region;

a gate metal layer covering the gate dielectric layer, a vertical projection of the gate metal layer covering the channel region;

an interlayer dielectric layer covering the active region;

a source/drain metal layer penetrating the interlayer dielectric layer and electrically connected to the source region and drain region;

a planarization layer covering the interlayer dielectric layer and the source/drain metal layer;

an electrode layer penetrating the planarization layer and electrically connected to the source/drain metal layer;

and a pixel defining layer on the planarization layer and exposing the electrode layer.

According to one aspect of the invention, wherein the transparent laminate comprises:

a first substrate formed by a substrate extension in an adjacent thin film transistor;

a first dielectric layer covering the substrate, the first dielectric layer is formed by an extension of a gate dielectric layer in an adjacent thin film transistor;

a second dielectric layer covering the gate dielectric layer, the second dielectric layer is formed by an extension of an interlayer dielectric layer in an adjacent thin film transistor.

According to one aspect of the invention, wherein the thin film transistor further comprises a source/drain wiring layer electrically connected to the source/drain metal layer, and a gate wiring layer electrically connected to the gate metal layer;

wherein a density of source/drain wirings in the thin film transistor under the transparent region that is less than or equal to a density of source/drain wirings located under the display region;

wherein a density of gate wirings of the gate wiring layer below the transparent region is less than or equal to a density of gate wirings of the gate wiring layer under the display region.

According to one aspect of the invention, wherein projections of the source/drain trace layer and the gate trace layer in a horizontal direction separate from a projection of the transparent stack in the horizontal direction.

An intelligent terminal comprising a display panel and a sensor component located below the display panel, the display panel comprising at least one transparent region and a display region, wherein the transparent region has two-way light transmission, and has a transparent function and a display function, a sensor component is disposed under the transparent region, the display region surrounds the transparent region, a brightness of the transparent region is less than or equal to a brightness of the display region.

According to one aspect of the invention, wherein the sensor component comprises a light sensor.

According to one aspect of the invention, wherein the sensor component is a camera and/or a graphics recognizer.

### Beneficial Effects

The display panel provided by the invention has a transparent region and a display region, the transparent region has both a transparent function and a display function, and can enable light outside the display panel to enter the inside of the display panel without affecting the display function of the display panel, and reach the light sensor located below the display panel. Therefore, the functions of imaging, image recognition, and the like can be realized without profile cutting.

### BRIEF DESCRIPTION OF DRAWINGS

FIG. 1 is a structural diagram of a display panel in an embodiment of the present invention.

FIG. 2 is a partial enlarged structural diagram of a display panel in an embodiment of the present invention.

FIG. 3 is a partial structural diagram of a ‘display region in a specific embodiment of the present invention.

FIG. 4 is a partial structural diagram of a light transmitting region in a specific embodiment of the present invention.

FIG. 5 is a partial structural diagram of a gate trace of a display panel in an embodiment of the present invention.

FIG. 6 is a partial structural diagram of a source and drain trace of a display panel in an embodiment of the present invention.

FIG. 7 to FIG. 11 are structural diagrams of a display panel in another embodiment of the present invention.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

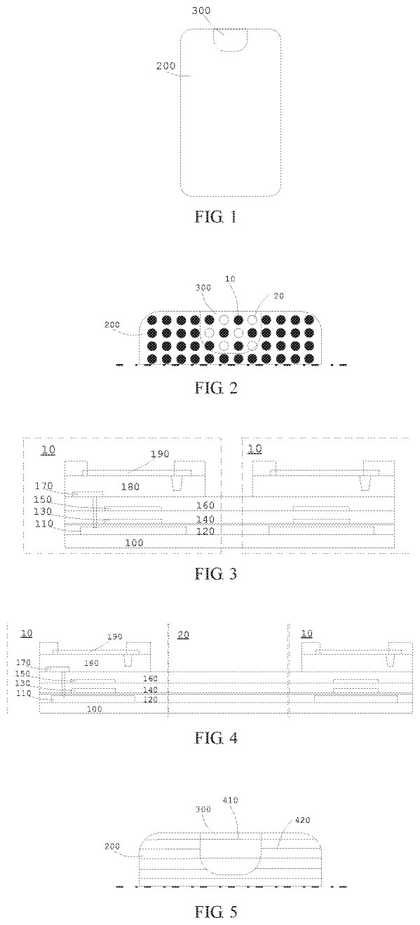

The present invention provides a display panel and an intelligent terminal, which can integrate light sensor into the display panel to avoid profile cutting. Referring to FIG. 1 and FIG. 2, FIG. 1 is a structural diagram of a display panel in an embodiment of the present invention, FIG. 2 is a partial enlarged structural diagram of a display panel in an embodiment of the present invention.

In the present embodiment, the display panel including at least one transparent region 300 and a display region 200, wherein the transparent region 300 has two-way light transmission, and has a transparent function and a display function, a sensor component is disposed under the transparent region 300, the display region 200 surrounds the transparent region 300, a brightness of the transparent region 300 is less than or equal to a brightness of the display region 200.

In some embodiments of the present invention, a number of the transparent regions 300 could be one, as shown in FIGS. 7 to 9. The transparent regions 300 can be located at a side of the display panel, and at least one side of the transparent region 300 overlaps with at least one side of the display panel, as shown in FIGS. 8 and 9. The light transmissive area 300 is located at a center of the display panel, and the transparent region 300 is surrounded by the display region 200.

In other embodiments of the present invention, a number of the transparent regions is plural, wherein the transparent regions 300 are separated by the display region 200. A position of at least one of the sides of any one of the transparent regions 300 overlaps with at least one side of the display panel. Or the transparent regions 300 are located at a center of the display panel and is surrounded by the display region 200.

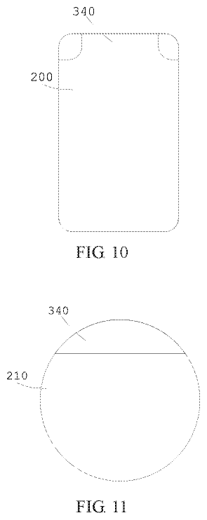

In some embodiments of the invention, the display panel are rectangular, as shown in FIG. 7 to FIG. 10. Rectangular display panels are mostly used in mobile terminals such as smartphones and tablets. In other embodiments of the invention, the display panel can be circular as shown in FIG. 11. Circular display panels are mostly used for smart watches, intelligent phones such as glasses. In the present invention, the display panel and the transparent region and the display region of the display panel can be any possible shape. The shapes, sizes, and positions of the display panel and the transparent region and the display region of the display panel in the above embodiments are merely illustrative of the invention and are not to be construed as limiting the invention.

Referring to FIG. 2, a density of the pixel units 10 in the transparent region 300 is less than or equal to the density of the pixel units 10 in the display region 200. Specifically, the transparent region 300 includes a plurality of pixel units 10 and a plurality of transparent units 20, the pixel unit 10 is spaced apart from the transparent unit 20, the area of the pixel unit 10 is less than or equal to the area of the transparent unit 20. The display region 300 includes a plurality of pixel units 10.

Referring to FIG. 3 and FIG. 4, FIG. 3 is a partial structural diagram of a display region in a specific embodiment of the present invention, FIG. 4 is a partial structural diagram of a light transmitting region in a specific embodiment of the present invention. The display panel includes a thin film transistor layer electrically connected to the pixel units 10. Wherein the thin film transistor layer located under the transparent region 300 include a thin film transistor corresponding to the pixel units 10 and a transparent laminate corresponding to the transparent unit 20. Wherein thin film transistor layer located under the display region 200 includes a thin film transistor corresponding to the pixel units 10. A density of the thin film transistor in the thin film transistor layer under the transparent region 300 is smaller than a density of a thin film transistor in a thin film transistor layer under the display region 200.

In the present embodiment, the thin film transistor includes: a substrate 100, an active region 110 on the substrate 100, the active region 110 includes a channel region and a source region and a drain region on both sides of the channel region, a gate dielectric layer 120 covering the active region 110, a gate metal layer 130 covering the gate dielectric layer 120, a vertical projection of the gate metal layer 130 covering the channel region, an interlayer dielectric layer 160 covering the active region, a source/drain metal layer 170 penetrating the interlayer dielectric layer 160 and electrically connected to the source region and drain region, a planarization layer 180 covering the interlayer dielectric layer 160 and the source/drain metal layer 170, an electrode layer 190 penetrating the planarization layer and electrically connected to the source/drain metal layer, and a pixel defining layer on the planarization layer 180 and exposing the electrode layer 190.

The transparent laminate includes: a first substrate 100 formed by a substrate extension in an adjacent thin film transistor, a first dielectric layer covering the substrate, the first dielectric layer is formed by an extension of a gate dielectric layer 120 in an adjacent thin film transistor, a second dielectric layer covering the gate dielectric layer, the second dielectric layer is formed by an extension of an interlayer dielectric layer 160 in an adjacent thin film transistor.

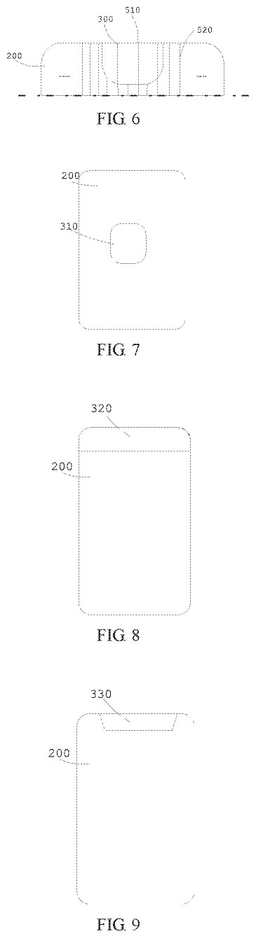

Referring to FIG. 5 and FIG. 6, FIG. 5 is a partial structural diagram of a gate trace of a display panel in an embodiment of the present invention, FIG. 6 is a partial structural diagram of a source and drain trace of a display panel in an embodiment of the present invention. In the present embodiment, the thin film transistor further includes a source/drain wiring layer electrically connected to the source/drain metal layer, and a gate wiring layer electrically connected to the gate metal layer. Wherein a density of source/drain wirings 510 in the thin film transistor under the transparent region 300 that is less than or equal to a density of source/drain wirings 520 located under the display region 200. Wherein a density of gate wirings 410 of the gate wiring layer below the transparent region 300 is less than or equal to a density of gate wirings 420 of the gate wiring layer under the display region 200.

Because the source/drain wirings and the gate wiring are generally opaque metal layers, in order to prevent the metal layer from shielding the transparent laminate in the first region, in this embodiment, projections of the source/drain wiring layer and the gate wiring layer in a horizontal direction separate from a projection of the transparent stack in the horizontal direction.

Correspondingly, the present invention also provides an intelligent terminal including a display panel and a sensor component located below the display panel, the display panel including at least one transparent region 300 and a display region 200, wherein the transparent region 300 has two-way light transmission, and has a transparent function and a display function, a sensor component is disposed under the transparent region 300, the display region 200 surrounds the transparent region 300, a brightness of the transparent region 300 is less than or equal to a brightness of the display region 200.

The sensor component includes a light sensor, such as a camera and/or a graphics recognizer, which can realize the function of under-screen camera and/or under-screen fingerprint recognition.

In the present embodiment, the display panel including at least one transparent region 300 and a display region 200, wherein the transparent region 300 has two-way light transmission, and has a transparent function and a display function, a sensor component is disposed under the transparent region 300, the display region 200 surrounds the transparent region 300, a brightness of the transparent region 300 is less than or equal to a brightness of the display region 200.

In some embodiments of the present invention, a number of the transparent regions 300 could be one, as shown in FIGS. 7 to 9. The transparent regions 300 can be located at a side of the display panel, and at least one side of the transparent region 300 overlaps with at least one side of the display panel, as shown in FIGS. 8 and 9. The light transmissive area 300 is located at a center of the display panel, and the transparent region 300 is surrounded by the display region 200.

In other embodiments of the present invention, a number of the transparent regions is plural, wherein the transparent regions 300 are separated by the display region 200. A position of at least one of the sides of any one of the transparent regions 300 overlaps with at least one side of the display panel. Or the transparent regions 300 are located at a center of the display panel and is surrounded by the display region 200.

In some embodiments of the invention, the display panel are rectangular, as shown in FIG. 7 to FIG. 10. Rectangular display panels are mostly used in mobile terminals such as smartphones and tablets. In other embodiments of the invention, the display panel can be circular as shown in FIG. 11. Circular display panels are mostly used for smart watches, intelligent phones such as glasses. In the present invention, the display panel and the transparent region and the display region of the display panel can be any possible shape. The shapes, sizes, and positions of the display panel and the transparent region and the display region of the display panel in the above embodiments are merely illustrative of the invention and are not to be construed as limiting the invention.

Referring to FIG. 2, a density of the pixel units 10 in the transparent region 300 is less than or equal to the density of the pixel units 10 in the display region 200. Specifically, the transparent region 300 includes a plurality of pixel units 10 and a plurality of transparent units 20, the pixel unit 10 is spaced apart from the transparent unit 20, the area of the pixel unit 10 is less than or equal to the area of the transparent unit 20. The display region 300 includes a plurality of pixel units 10.

Referring to FIG. 3 and FIG. 4, FIG. 3 is a partial structural diagram of a display region in a specific embodiment of the present invention, FIG. 4 is a partial structural diagram of a light transmitting region in a specific embodiment of the present invention. The display panel includes a thin film transistor layer electrically connected to the pixel units 10. Wherein the thin film transistor layer located under the transparent region 300 include a thin film transistor corresponding to the pixel units 10 and a transparent laminate corresponding to the transparent unit 20. Wherein thin film transistor layer located under the display region 200 includes a thin film transistor corresponding to the pixel units 10. A density of the thin film transistor in the thin film transistor layer under the transparent region 300 is smaller than a density of a thin film transistor in a thin film transistor layer under the display region 200.

In the present embodiment, the thin film transistor includes: a substrate 100, an active region 110 on the substrate 100, the active region 110 includes a channel region and a source region and a drain region on both sides of the channel region, a gate dielectric layer 120 covering the active region 110, a gate metal layer 130 covering the gate dielectric layer 120, a vertical projection of the gate metal layer 130 covering the channel region, an interlayer dielectric layer 160 covering the active region, a source/drain metal layer 170 penetrating the interlayer dielectric layer 160 and electrically connected to the source region and drain region, a planarization layer 180 covering the interlayer dielectric layer 160 and the source/drain metal layer 170, an electrode layer 190 penetrating the planarization layer and electrically connected to the source/drain metal layer, and a pixel defining layer on the planarization layer 180 and exposing the electrode layer 190.

The transparent laminate includes: a first substrate 100 formed by a substrate extension in an adjacent thin film transistor, a first dielectric layer covering the substrate, the first dielectric layer is formed by an extension of a gate dielectric layer 120 in an adjacent thin film transistor, a second dielectric layer covering the gate dielectric layer, the second dielectric layer is formed by an extension of an interlayer dielectric layer 160 in an adjacent thin film transistor.

Referring to FIG. 5 and FIG. 6, FIG. 5 is a partial structural diagram of a gate trace of a display panel in an embodiment of the present invention, FIG. 6 is a partial structural diagram of a source and drain trace of a display panel in an embodiment of the present invention. In the present embodiment, the thin film transistor further includes a source/drain wiring layer electrically connected to the source/drain metal layer, and a gate wiring layer electrically connected to the gate metal layer. Wherein a density of source/drain wirings 510 in the thin film transistor under the transparent region 300 that is less than or equal to a density of source/drain wirings 520 located under the display region 200. Wherein a density of gate wirings 410 of the gate wiring layer below the transparent region 300 is less than or equal to a density of gate wirings 420 of the gate wiring layer under the display region 200.

Because the source/drain wirings and the gate wiring are generally opaque metal layers, in order to prevent the metal layer from shielding the transparent laminate in the first region, in this embodiment, projections of the source/drain wiring layer and the gate wiring layer in a horizontal direction separate from a projection of the transparent stack in the horizontal direction.

The display panel provided by the invention has a transparent region and a display region, the transparent region has both a transparent function and a display function, and can enable light outside the display panel to enter the inside of the display panel without affecting the display function of the display panel, and reach the light sensor located below the display panel. Therefore, the functions of imaging, image recognition, and the like can be realized without profile cutting.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

1. A display panel comprising at least one transparent region and a display region, wherein the at least one transparent region has two-way light transmission, and has a transparent function and a display function, a sensor component is disposed under the at least one transparent region, the display region surrounds the at least one transparent region, a brightness of the transparent region is less than or equal to a brightness of the display region;
wherein the transparent region is located at a side of the display panel, and at least one side of the transparent region overlaps with at least one side of the display panel;
or
the transparent region is located at a center of the display panel and surrounded by the display region.

2. (canceled)

3. The display panel according to claim 1, wherein a density of pixel units in the transparent region is less than or equal to a density of pixel units in the display region;
wherein the transparent region comprises a plurality of pixel units and a plurality of transparent units, the pixel units are spaced apart from the transparent unit, and a region of the pixel units is less than or equal to a region of the transparent units;
wherein the display region comprises a plurality of pixel units.

4. The display panel according to claim 3, wherein the display panel comprises a thin film transistor layer electrically connected to the pixel units;
wherein the thin film transistor layer located under the transparent region comprise a thin film transistor corresponding to the pixel units and a transparent laminate corresponding to the transparent unit;
wherein thin film transistor layer located under the display region comprises a thin film transistor corresponding to the pixel units.

5. The display panel according to claim 4, wherein a density of the thin film transistor in the thin film transistor layer under the transparent region is smaller than a density of a thin film transistor in a thin film transistor layer under the display region.

6. The display panel according to claim 4, wherein the thin film transistor comprises:
a substrate;
an active region on the substrate, the active region comprises a channel region and a source region and a drain region on both sides of the channel region;
a gate dielectric layer covering the active region;
a gate metal layer covering the gate dielectric layer, a vertical projection of the gate metal layer covering the channel region;
an interlayer dielectric layer covering the active region;
a source/drain metal layer penetrating the interlayer dielectric layer and electrically connected to the source region and drain region;
a planarization layer covering the interlayer dielectric layer and the source/drain metal layer;
an electrode layer penetrating the planarization layer and electrically connected to the source/drain metal layer;
and a pixel defining layer on the planarization layer and exposing the electrode layer.

7. The display panel according to claim 6, wherein the transparent laminate comprises:
a first substrate formed by a substrate extension in an adjacent thin film transistor;
a first dielectric layer covering the substrate, the first dielectric layer is formed by an extension of a gate dielectric layer in an adjacent thin film transistor;
a second dielectric layer covering the gate dielectric layer, the second dielectric layer is formed by an extension of an interlayer dielectric layer in an adjacent thin film transistor; and
the thin film transistor further comprises a source/drain wiring layer electrically connected to the source/drain metal layer, and a gate wiring layer electrically connected to the gate metal layer;
wherein a density of source/drain wirings in the thin film transistor under the transparent region that is less than or equal to a density of source/drain wirings located under the display region;
wherein a density of gate wirings of the gate wiring layer below the transparent region is less than or equal to a density of gate wirings of the gate wiring layer under the display region;
wherein projections of the source/drain trace layer and the gate trace layer in a horizontal direction separate from a projection of the transparent stack in the horizontal direction.

8. A display panel comprising at least one transparent region and a display region, wherein the at least one transparent region has two-way light transmission, and has a transparent function and a display function, a sensor component is disposed under the at least one transparent region, the display region surrounds the at least one transparent region, a brightness of the at least one transparent region is less than or equal to a brightness of the display region.

9. The display panel according to claim 8,
wherein the at least one transparent region is located at a side of the display panel, and at least one side of the at least one transparent region overlaps with at least one side of the display panel; or
the at least one transparent region is located at a center of the display panel and surrounded by the display region.

10. (canceled)

11. The display panel according to claim 8, wherein a density of pixel units in the transparent region is less than or equal to a density of pixel units in the display region;
wherein the transparent region comprises a plurality of pixel units and a plurality of transparent units, the pixel units are spaced apart from the transparent unit, and a region of the pixel units is less than or equal to a region of the transparent units;
wherein the display region comprises a plurality of pixel units.

12. The display panel according to claim 11, wherein the display panel comprises a thin film transistor layer electrically connected to the pixel units;
wherein the thin film transistor layer located under the transparent region comprise a thin film transistor corresponding to the pixel units and a transparent laminate corresponding to the transparent unit;
wherein thin film transistor layer located under the display region comprises a thin film transistor corresponding to the pixel units.

13. The display panel according to claim 12, wherein a density of the thin film transistor in the thin film transistor layer under the transparent region is smaller than a density of a thin film transistor in a thin film transistor layer under the display region.

14. The display panel according to claim 12, wherein the thin film transistor comprises:
a substrate;
an active region on the substrate, the active region comprises a channel region and a source region and a drain region on both sides of the channel region;
a gate dielectric layer covering the active region;
a gate metal layer covering the gate dielectric layer, a vertical projection of the gate metal layer covering the channel region;
an interlayer dielectric layer covering the active region;
a source/drain metal layer penetrating the interlayer dielectric layer and electrically connected to the source region and drain region;
a planarization layer covering the interlayer dielectric layer and the source/drain metal layer;
an electrode layer penetrating the planarization layer and electrically connected to the source/drain metal layer;
and a pixel defining layer on the planarization layer and exposing the electrode layer.

15. The display panel according to claim 14, wherein the transparent laminate comprises:
a first substrate formed by a substrate extension in an adjacent thin film transistor;
a first dielectric layer covering the substrate, the first dielectric layer is formed by an extension of a gate dielectric layer in an adjacent thin film transistor;
a second dielectric layer covering the gate dielectric layer, the second dielectric layer is formed by an extension of an interlayer dielectric layer in an adjacent thin film transistor.

16. The display panel according to claim 14, wherein the thin film transistor further comprises a source/drain wiring layer electrically connected to the source/drain metal layer, and a gate wiring layer electrically connected to the gate metal layer;
wherein a density of source/drain wirings in the thin film transistor under the transparent region that is less than or equal to a density of source/drain wirings located under the display region;
wherein a density of gate wirings of the gate wiring layer below the transparent region is less than or equal to a density of gate wirings of the gate wiring layer under the display region.

17. The display panel according to claim 16, wherein projections of the source/drain trace layer and the gate trace layer in a horizontal direction separate from a projection of the transparent stack in the horizontal direction.

18. An intelligent terminal comprising a display panel and a sensor component located below the display panel, the display panel comprising at least one transparent region and a display region, wherein the at least one transparent region has two-way light transmission, and has a transparent function and a display function, a sensor component is disposed under the at least one transparent region, the display region surrounds the at least one transparent region, a brightness of the at least one transparent region is less than or equal to a brightness of the display region.

19. The intelligent terminal according to claim 18, wherein the sensor component comprises a light sensor.

20. The intelligent terminal according to claim 19, wherein the sensor component is a camera and/or a graphics recognizer.
